(19) United States
(12) Patent Application Publication
(10) Pub. No.: US 2020/0408840 A1
(43) Pub. Date: Dec. 31, 2020

(54) HEALTH MONITOR CIRCUIT FOR AN ELECTRIC MACHINE

(71) Applicant: Regal Beloit America, Inc., Beloit, WI (US)

(72) Inventors: Christopher Edwin Eugene Propp, Wausau, WI (US); Myron Roman Mychal, Schofield, WI (US)

(21) Appl. No.: 16/946,600

(22) Filed: Jun. 29, 2020

Related U.S. Application Data
(60) Provisional application No. 62/868,368, filed on Jun. 28, 2019.

(51) Int. Cl. G01R 31/34; G05B 19/042

(52) U.S. Cl. CPC G01R 31/343; G05B 2219/24015; G05B 19/0428

(57) ABSTRACT

A health monitor circuit for an electric machine is described. The health monitor circuit includes at least one sensor configured to measure a parameter of the electric machine, a communication interface, and a microprocessor coupled to the at least one sensor, the communication interface, and a memory. The microprocessor is configured to periodically collect time samples of the parameter measured by the at least one sensor, transmit factors of the time samples to the memory, and perform a high resolution fast-Fourier transform (FFT) on the factors. The microprocessor is also configured to extrapolate results of the high resolution FFT to a produce a high resolution frequency domain waveform, filter the high resolution frequency domain waveform by a parameter, and transmit, via the communication interface, the filtered frequency domain waveform to a remote system for further processing.

### CROSS REFERENCE TO RELATED APPLICATIONS

The present application claims the benefit of and priority to U.S. Provisional Patent Application No. 62/868,368, filed Jun. 28, 2019, and entitled “HEALTH MONITOR CIRCUIT FOR AN ELECTRIC MACHINE,” the disclosure of which is hereby incorporated by reference in its entirety.

### FIELD

The field of the disclosure relates generally to a health monitor circuit for an electric machine and, more specifically, a microprocessor for health monitor circuits that provides improved fast-Fourier transform (FFT), improved data compression for transmission, and improved stator current signature analysis.

### BACKGROUND

At least some electric machines include one or more sensors as part of a health monitor to periodically measure, for example, vibrations, ambient temperature, current, voltage, humidity, torque, or other parameters. Such measurements can be useful in determining, for example, the amount of wear experienced by the electric machine over time as well as the general health of the electric machine or, in the case of motoring, at least some aspects of the operation of the load. Certain electric machines include, for example, piezo-electric accelerometers to measure vibration. Certain electric machines include, for example, resistance temperature sensors (RTDs) embedded in circuitry of the electric machine to monitor temperature. Such sensors can be integrated into the electric machine and its housing, and are generally powered by batteries, a power management circuit, or otherwise supplied power independent of the electric machine itself.

Some electric machines (electrically commutated motors (ECMs), for example) include current sensors integrated onto a controller (e.g., a motor controller) for measuring stator currents to properly operate the electric machine. Other electric machines (induction motors, for example) do not need to measure stator currents to operate. Current sensors for monitoring operation of ECMs or induction motors for diagnostic or health monitoring purposes are sometimes periodically installed for brief durations to gather stator current data for analysis. For example, an external motor current module may be installed on an electric machine quarterly to monitor health of the ECM or induction motor for a number of hours, days, or other representative duration.

Data collected by sensors can be used and stored locally on the electric machine and, more specifically, on a memory device integrated within the housing or integrated within a microprocessor that is itself integrated within the housing or attached thereto. Alternatively, the data collected by the sensors may be transferred to a remote memory device such as, for example, a mass storage device or a cloud server using wired or wireless communications. In either implementation, the performance of the health monitor circuit is often limited in speed, resolution, or storage by the physical size, memory capacity, or power consumption of the microprocessor for the health monitor circuit. Such health monitor circuits may be further limited in the volume of data that can be collected and transmitted for remote processing. Consequently, at least some data collection and analysis, such as stator current signature analysis (e.g., motor current signature analysis) is limited to being carried out using external modules with greater capacity for processing and storage than can be integrated within a motor controller or within a health monitor circuit integrated within the housing of the electric machine or attached thereto. It is desirable to improve the performance of health monitor circuits for electric machines.

### BRIEF DESCRIPTION

In one aspect, a health monitor circuit for an electric machine is described. The health monitor circuit includes at least one sensor configured to measure a parameter of the electric machine, a communication interface, and a microprocessor coupled to the at least one sensor, the communication interface, and a memory. The microprocessor is configured to periodically collect time samples of the parameter measured by the at least one sensor, transmit factors of the time samples to the memory, and perform a high resolution fast-Fourier transform (FFT) on the factors. The microprocessor is also configured to extrapolate results of the high resolution FFT to a produce a high resolution frequency domain waveform, filter the high resolution frequency domain waveform by a parameter, and transmit, via the communication interface, the filtered frequency domain waveform to a remote system for further processing.

In another aspect, a method for monitoring the health of an electric machine, wherein the electric machine comprises at least one sensor configured to measure a parameter of the electric machine, a communication interface, and a microprocessor coupled to the at least one sensor, the communication interface, and a memory, is described. The method includes periodically collecting time samples of the parameter measured by at least one sensor, transmitting factors of the time samples to the memory, and performing a high resolution fast-Fourier transform (FFT) on the factors. The method also includes extrapolating results of the high resolution FFT to a produce a high resolution frequency domain waveform, filtering the high resolution frequency domain waveform by a parameter, and transmitting, via the communication interface, the filtered frequency domain waveform to a remote system for further processing.

In yet another aspect, a health monitor system is described. The health monitor system includes an electric machine and a health monitor circuit coupled to the electric machine. The health monitor circuit includes at least one sensor configured to measure a parameter of the electric machine, a communication interface, and a microprocessor coupled to the at least one sensor, the communication interface, and a memory. The microprocessor is configured to periodically collect time samples of the parameter measured by the at least one sensor, transmit factors of the time samples to the memory, and perform a high resolution fast-Fourier transform (FFT) on the factors. The microprocessor is also configured to extrapolate results of the high resolution FFT to a produce a high resolution frequency domain waveform, filter the high resolution frequency domain waveform by a parameter, and transmit, via the communication interface, the filtered frequency domain waveform to a remote system for further processing.

### BRIEF DESCRIPTION OF THE DRAWINGS

FIG. 1 is a block diagram of an example electric machine having a health monitor circuit;

FIG. 2 is a graph illustrating symmetry in a cosine wave and an example time domain waveform data set;

FIG. 3 is a graph illustrating example improvements in FFT performance of an example embodiment of a health monitor circuit;

FIG. 4 is a graph illustrating example time domain acceleration waveforms for an electric machine;

FIG. 5 is a graph illustrating example frequency domain acceleration waveforms derived from the time domain acceleration waveforms shown in FIG. 4;

FIG. 6 is a graph illustrating the frequency domain acceleration waveforms shown in FIG. 5 after amplitude filtering; and

FIG. 7 is a flow diagram of an example method of collecting motor current data for motor current signature analysis.

### DETAILED DESCRIPTION

Embodiments of the health monitor circuit described herein provide a health monitor circuit for an electric machine, including a microprocessor having improved fast-Fourier transform (FFT) performance utilizing less memory and with greater resolution than otherwise available alternatives. The improved FFT performance is achieved, for example, by storing and operating on symmetric factors of a cosine wave, or “Twiddle Factors,” and later extrapolating the FFT results to reconstruct the full waveform with a greater resolution in the frequency domain. In certain embodiments, the health monitor circuit described herein includes a microprocessor having improved data compression for transmission of collected data to remote systems. The microprocessor converts collected data to the frequency domain and filters based on one or more parameters to affect the compression. For example, the frequency domain data may be reduced based on local maximums that represent the most critical data within the frequency domain data. This reduction may be achieved, for example, by amplitude filtering. In certain embodiments, the health monitor circuit is provided within an electric machine and enables high-resolution stator current signature analysis either by the microprocessor integrated thereon or by a remote system. The health monitor circuits described herein include current sense circuits that enable periodic collection and storage of stator current measurements (and other measurements of operating parameters and environmental conditions) controlled by a microprocessor or other suitable processing device.

Health monitor circuit described herein includes one or more sensors for detecting operating parameters and environmental conditions for the electric machine, including, for example, ambient temperature, ambient humidity, barometric pressure, acceleration, and stator current. The health monitor circuit measurements enables improved analysis and monitoring of electrical and mechanical degradation, or “wear,” experienced by the electric machine, and further enables inferences of various aspects of the health of the mechanical load (for electric motors) coupled to and driven by the electric motor, or the health of the machine or other drive coupled to and turning the rotor (for electric generators). The health monitor circuits described herein may further include voltage regulating and power distribution circuits for generating and supplying power to components of the health monitor circuit.

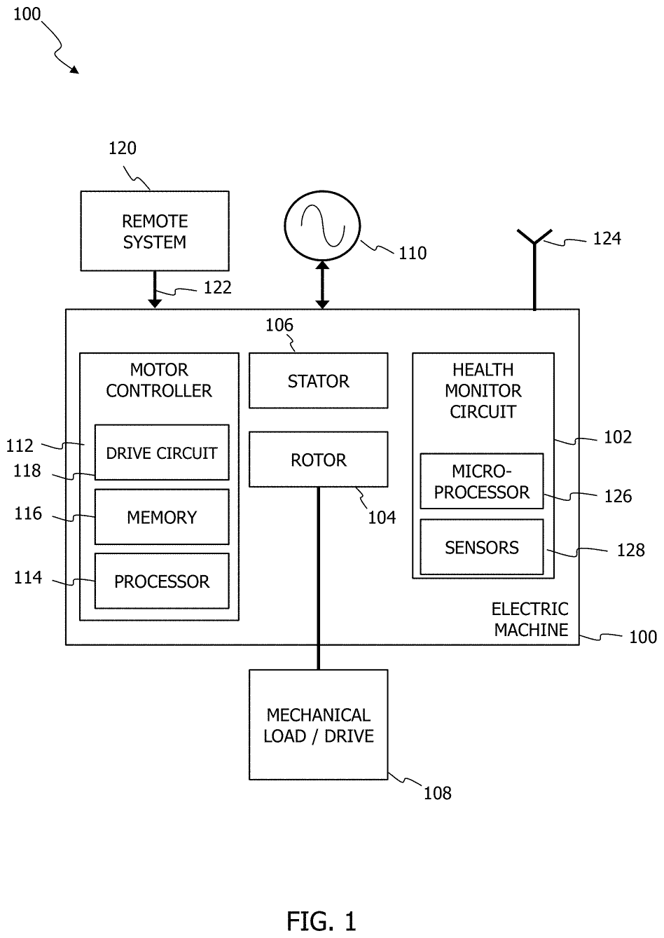

FIG. 1 is a block diagram of an example electric machine 100 having a health monitor circuit 102. Electric machine 100 is illustrated as an electric motor that includes a rotor 104 and a stator 106. Rotor 104 is configured to be coupled to a mechanical load (or drive) 108. Mechanical load 108 may include, for example, a rotatable load such as a fan, wheel, blower, impeller, compressor, fly wheel, transmission, or crank shaft, among others. Mechanical load 108 may also include a linear load, such as a solenoid or linear actuator, among others. In alternative embodiments, rotor 104 is configured to be coupled to a machine or other drive that turns rotor 104 to operate electric machine 100 as an electric generator. Such a machine may include a combustion engine, gas turbine, wind turbine, steam turbine, or any other suitable machine for turning rotor 104. Referring again to the embodiment of FIG. 1 in which electric machine 100 is an electric motor, stator 106 generally includes one or more stator windings (not shown) that, when energized and conducting stator current, are electromagnetically coupled to rotor 104 and cause rotor 104 to turn, about a longitudinal axis, with respect to stator 106.

Electric machine 100 is supplied (or supplies) alternating current (AC) from an AC source 110 (or electrical load). AC source 110 may include, for example, an electrical grid, a diesel, wind, or turbine generator, or any other suitable AC source. AC source 110 may alternatively include one or more direct current (DC) sources having an output that is converted, or “inverted,” to an AC power before being supplied to electric machine 100. AC power from AC source 110, in certain embodiments, may be applied directly to stator 106. In alternative embodiments, electric machine 100 may be supplied AC or DC power that is appropriately converted to AC and/or DC by electric machine 100 itself. For this purpose, among others, some embodiments of electric machine 100 include a motor controller 112. In other embodiments, motor controller 112 may be omitted.

Motor controller 112 generally includes one or more processors 114, one or more memory devices 116, and a drive circuit 118. Generally, drive circuit 118 supplies electric power to stator 106 of electric machine 100 based on control signals received from the one or more processors 114. Drive circuit 118 may include, for example, various power electronics for conditioning line frequency AC power to be supplied to the stator windings of electric machine 100 with a desired current, i.e., phase and amplitude, and frequency. Such power electronics may include, for example, and without limitation, one or more rectifier stages, power factor correction (PFC) circuits, filters, transient protection circuits, EMF protection circuits, inverters, or power semiconductors. Motor controller 112, in certain embodiments, may include a communication interface (not shown). The communication interface may include one or more wired or wireless hardware interface, such as, for example, universal serial bus (USB), RS232 or other serial bus, CAN bus, Ethernet, near field communication (NFC), WiFi, Bluetooth, or any other suitable digital or analog interface for establishing one or more communication channels between motor controller 112 and a remote system 120. Remote system 120 may include a system controller, smart phone, personal computer, mass storage system, cloud server, or any other suitable computing system. The communication interface may include, for example, a wired communication channel 122 to remote system 120 or an antenna 124 for establishing a wireless communication channel with remote system 120. The communication interface further includes a software or firmware interface for receiving one or more control parameters and writing them, for example, to memory. In certain embodiments, the communication interface includes, for example, a software application programming interface (API) for supplying one or more parameters for operating electric machine 100.

In alternative embodiments, the communication interface may be implemented independent of motor controller 112 such that it serves both motor controller 112 and health monitor circuit 102. In a further alternative embodiment, the communication interface may be incorporated into health monitor circuit 102 instead of or in addition to motor controller 112.

Electric machine 100 may include a casing within which rotor 104 and stator 106 are located. Electric machine 100 may also include an electrical housing, or “conduit box,” within which various electrical components of electric machine 100 may be located, such as, for example, motor controller 112 and health monitor circuit 102.

Health monitor circuit 102 includes one or more microprocessor 126 and one or more sensor 128. Microprocessor 126, in certain embodiments, includes a processing core capable of carrying out at least floating point arithmetic computations and, in some embodiments, digital signal processing. Microprocessor 126 may further include one or more analog-to-digital converters (ADCs), and generally includes some volume of random access memory (RAM) and some volume of program memory, such as read-only memory (ROM), erasable programmable read-only memory (EPROM), electrically erasable programmable read-only memory (EEPROM). Microprocessor 126 may further include a plurality of input/output interfaces and one or more communication interfaces. Generally, given a particular physical size, power consumption limitations, or cost for health monitor circuit 102, the quantity and/or variety of interfaces, memory, and processing bandwidth that microprocessor 126 may provide may be limited. For example, the housing for health monitor circuit 102 may limit the physical footprint of microprocessor 126 such that microprocessor 126 may only provide limited ROM and RAM volume. Such memory limitations may further limit the resolution with which microprocessor 126 carries out data collection and offloading, via wired communication channel 122 or antenna 124, to remote system 120, for example, and may limit the capacity of remote system 120 to perform certain analysis.

Sensors 128, in certain embodiments, may include an ambient temperature sensor, an ambient humidity sensor, a barometric pressure sensor, or an acceleration sensor, such as a microelectromechanical systems (MEMS) triaxial accelerometer. Sensors 128 may also include one or more current sensors. Sensors 128 may include any other type of sensor or device for collecting analog or digital data from electric machine 100. Sensors 128 are configured to monitor various operating parameters and environmental conditions of or around electric machine 100. Sensors 128 may further enable monitoring of various operating parameters of mechanical load (or drive) 108. At least some of sensors 128 may be installed on electric machine 100 or, for example on motor controller 112, and transmit measurement data back to microprocessor 126.

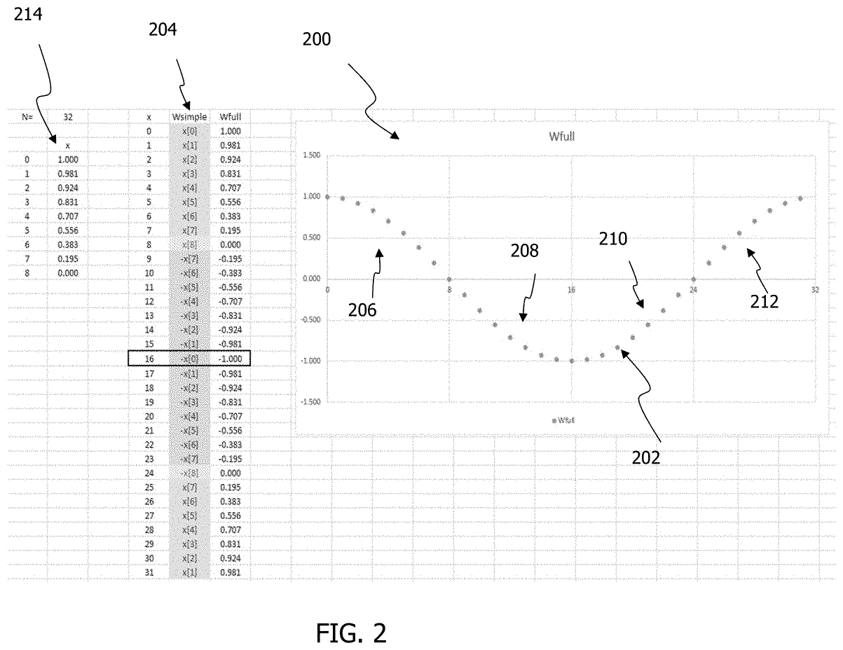

FIG. 2 is a graph 200 illustrating an example time domain waveform data set. More specifically, graph 200 includes a time domain waveform 202 represented by a plurality of time samples, acquired by sensors 128 of health monitor circuit 102, and which appear in a table as a full waveform data set 204. Time domain waveform 202 is a sinusoidal waveform and, thus, each quadrant of time domain waveform 202 shares a symmetric aspect, or factor, with a next quadrant. For example, a first quadrant 206 falls in amplitude from one to zero with a symmetric factor, i.e., rate of declination, as in a second quadrant 208. Likewise, the rate of declination in second quadrant 208 is symmetric with the rate of incline in a third quadrant 210, which itself is symmetric with the rate of incline in a fourth quadrant 212. Accordingly, this symmetric aspect may be “factored out” from time domain waveform 202 such that it may be stored, and operated on, as a series of factors 214, sometimes referred to as “twiddle factors,” instead of the full waveform data set 204. Factors 214 are generally computed in the form of EQ. 1, below, where W is a factor, N is the resolution, and m is an index.

$${W}_{N}^{m} = cos ( \frac{2 π}{N} m ) - j sin ( \frac{2 π}{N} m ) \qquad EQ . 1$$

Microprocessor 126 is configured, or programmed, to store and operate on factors 214, and then extrapolate from factors 214 to reconstruct a full waveform with greater resolution. For example, microprocessor 126 is programmed to perform a fast Fourier transform (FFT). Traditionally, a microprocessor may be limited to some maximum resolution, e.g., 4096 points. Microprocessor 126, however, is configured to perform the FFT using factors 214 and then extrapolates the results to produce a greater-resolution FFT, e.g., 16,384 points.

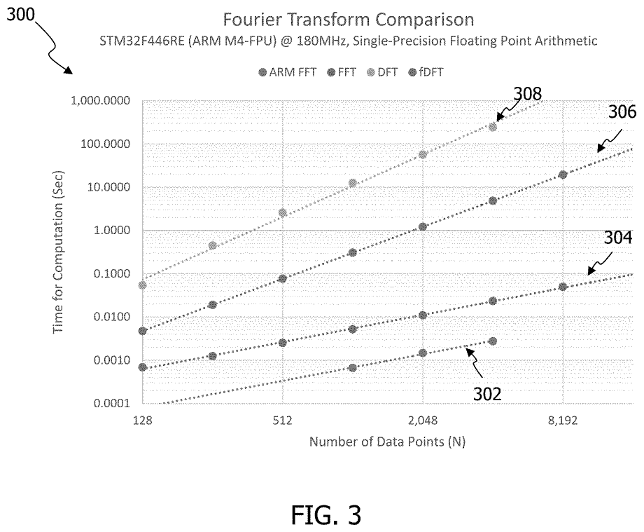

FIG. 3 is a graph 300 illustrating example improvements in FFT performance of an example embodiment of a health monitor circuit, such as health monitor circuit 102 shown in FIG. 1. Graph 300 includes a horizontal axis representing resolution, or FFT points, and a vertical axis representing time in seconds on a logarithmic scale. Graph 300 includes a plot 302 illustrating native FFT performance on a microprocessor comparable to microprocessor 126. Graph 300 includes a plot 304 illustrating FFT performance of microprocessor 126 for health monitor circuit 102 and configured as described above. Graph 300 includes plots 306 and 308 illustrating performance of fast discrete Fourier transform (fDFT) and discrete Fourier transform (DFT), respectively, on the microprocessor comparable to microprocessor 126. Plot 304 illustrates the improved resolution of the FFT carried out by microprocessor 126, while also increasing the computation time only modestly relative to that required by fDFT and DFT, as shown in plots 306 and 308. Likewise, the program code and data storage for the FFT implementation on microprocessor 126 can be stored in a portion of ROM that is a fraction (e.g., approximately ⅕) of that for the native FFT performance.

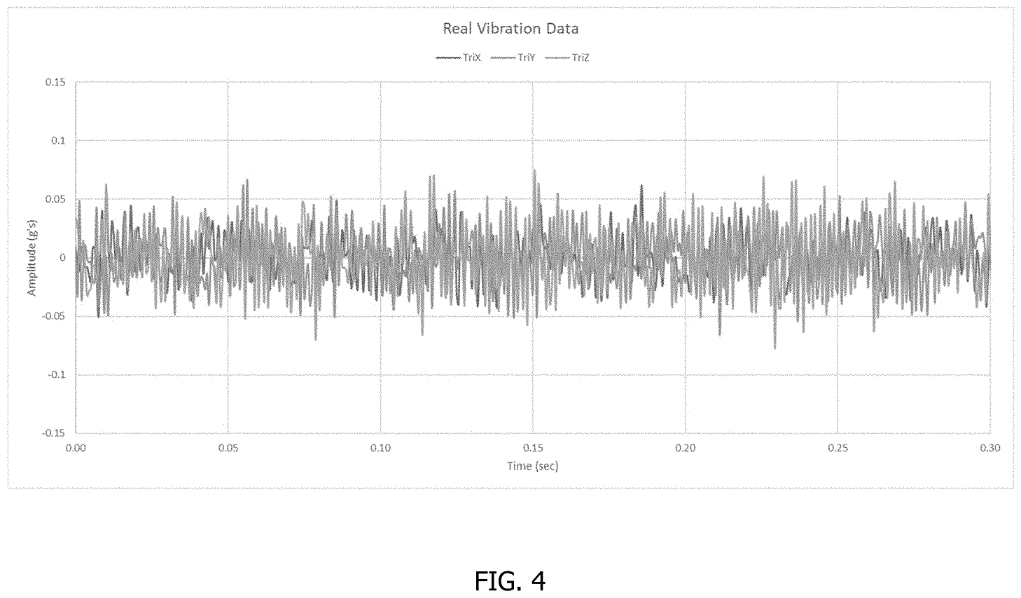

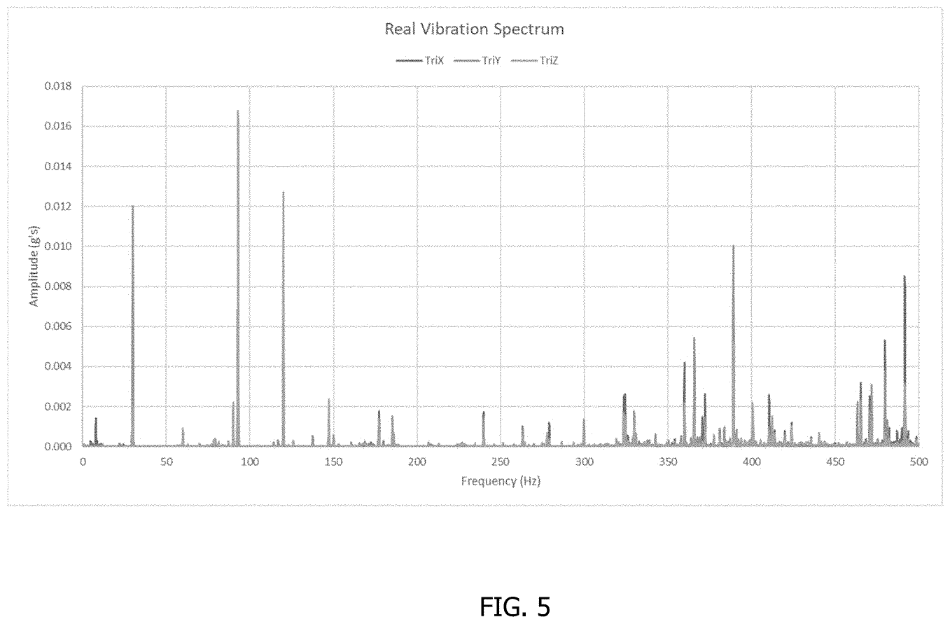

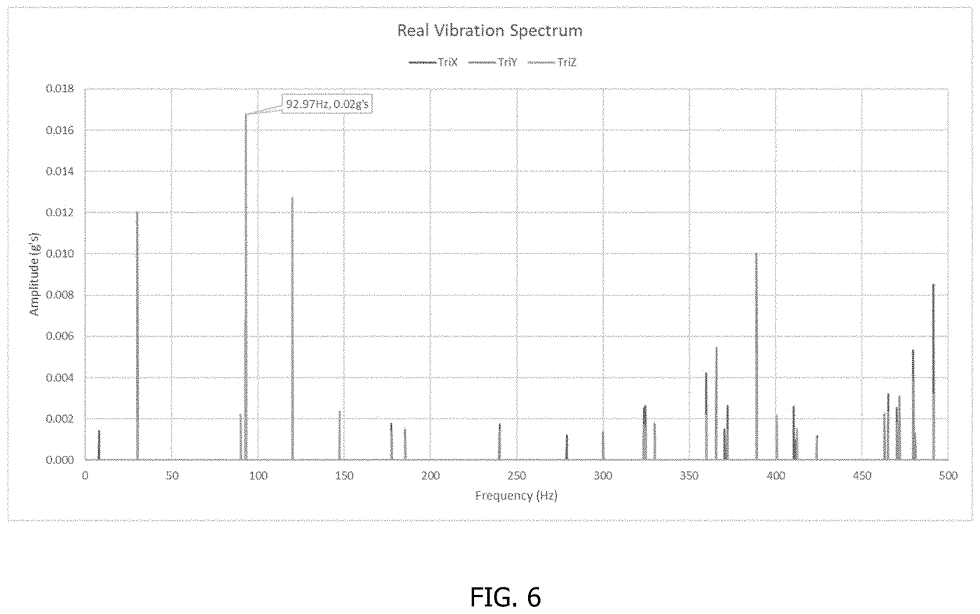

FIG. 4 is a graph illustrating example time domain acceleration waveforms for an electric machine, such as electric machine 100 shown in FIG. 1. Such acceleration waveforms may be collected using sensors 128, which may include, for example, a triaxial accelerometer that produces acceleration measurements on three axes (X, Y, Z). Accelerations are plotted against a vertical axis expressing acceleration in g's. The full time domain waveform data set for the three axes of acceleration measurements would require about 585 kilobyte (kB) to store in memory. Microprocessor 126 (shown in FIG. 1) is configured to convert, using the improved FFT implementation described above with respect to FIGS. 2 and 3, the time domain waveforms to frequency domain waveforms. FIG. 5 is a graph illustrating example frequency domain acceleration waveforms derived from the time domain acceleration waveforms shown in FIG. 4. FIG. 6 is a graph illustrating the frequency domain acceleration waveforms shown in FIG. 5 after amplitude filtering. Microprocessor 126 is configured to amplitude filter the frequency domain acceleration waveforms to remove peaks below a configurable acceleration threshold. The resulting “compressed” frequency domain data set is orders of magnitude smaller than the original time domain data set. For example, the filtered frequency domain acceleration waveforms shown in FIG. 6 would require about 0.36 kB to store in memory. Accordingly, microprocessor 126 is able to transmit the frequency domain data set in a more efficient manner over wired communication channel 122 or via antenna 124 to remote system 120 for further processing.

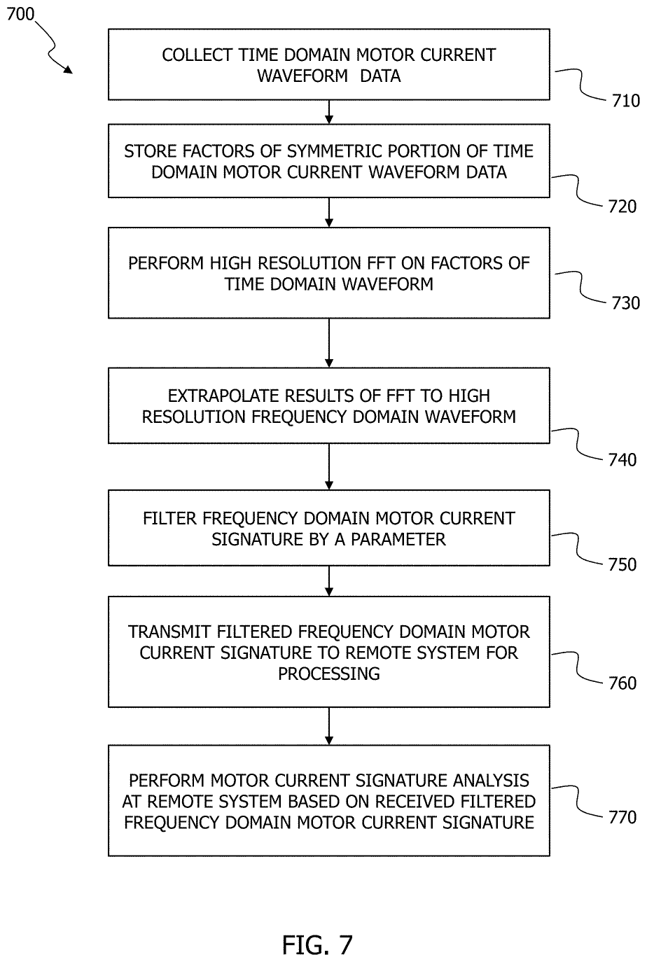

FIG. 7 is a flow diagram of an example method 700 of collecting motor current data for motor current signature analysis. Method 700 may be embodied, for example, in electric machine 100. Health monitor circuit 102 collects 710 time domain motor current data representing a motor current waveform. Time domain motor current data is collected by one or more sensors 128 that measure stator currents. Factors of the symmetric portions of the time domain current waveform data are stored 720 in memory, such as RAM. Microprocessor 126 then performs 730 a high-resolution FFT on the factors of the time domain waveform. Microprocessor 126 then extrapolates 740 the results of the FFT to produce a high resolution frequency domain stator current waveform. Microprocessor 126 filters 750 the frequency domain waveform by one or more parameter, such as amplitude. For example, by removing low amplitude frequency content and retaining the local maxima, the frequency domain waveform data set is further compressed. Microprocessor 126 then can transmit 760 the filtered frequency domain motor current signature to a remote system, such as remote system 120, for further processing. Remote system 120, for example, can perform motor current signature analysis to determine, for example, a condition of the electric machine or to infer operational conditions of the mechanical load.

The methods and systems described herein may be implemented using computer programming or engineering techniques including computer software, firmware, hardware or any combination or subset thereof, wherein the technical effect may include at least one of: (a) improving FFT performance; (b) improving data compression for storage and/or transmission; (c) enabling high resolution stator current signature analysis.

In the foregoing specification and the claims that follow, a number of terms are referenced that have the following meanings.

As used herein, an element or step recited in the singular and preceded with the word “a” or “an” should be understood as not excluding plural elements or steps, unless such exclusion is explicitly recited. Furthermore, references to “example implementation” or “one implementation” of the present disclosure are not intended to be interpreted as excluding the existence of additional implementations that also incorporate the recited features.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here, and throughout the specification and claims, range limitations may be combined or interchanged. Such ranges are identified and include all the sub-ranges contained therein unless context or language indicates otherwise.

Some embodiments involve the use of one or more electronic processing or computing devices. As used herein, the terms “microprocessor,” “processor,” and “computer” and related terms, e.g., “processing device,” “computing device,” and “controller” are not limited to just those integrated circuits referred to in the art as a computer, but broadly refers to a processor, a processing device, a controller, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processing (DSP) device, an application specific integrated circuit (ASIC), and other programmable circuits or processing devices capable of executing the functions described herein, and these terms are used interchangeably herein. The above embodiments are examples only, and thus are not intended to limit in any way the definition or meaning of the terms processor, processing device, and related terms.

In the embodiments described herein, memory may include, but is not limited to, a non-transitory computer-readable medium, such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROMs, DVDs, and any other digital source such as a network or the Internet, as well as yet to be developed digital means, with the sole exception being a transitory, propagating signal. Alternatively, a floppy disk, a compact disc-read only memory (CD-ROM), a magneto-optical disk (MOD), a digital versatile disc (DVD), or any other computer-based device implemented in any method or technology for short-term and long-term storage of information, such as, computer-readable instructions, data structures, program modules and sub-modules, or other data may also be used. Therefore, the methods described herein may be encoded as executable instructions, e.g., “software” and “firmware,” embodied in a non-transitory computer-readable medium. Further, as used herein, the terms “software” and “firmware” are interchangeable, and include any computer program stored in memory for execution by personal computers, workstations, clients and servers. Such instructions, when executed by a processor, cause the processor to perform at least a portion of the methods described herein.

Also, in the embodiments described herein, additional input channels may be, but are not limited to, computer peripherals associated with an operator interface such as a mouse and a keyboard. Alternatively, other computer peripherals may also be used that may include, for example, but not be limited to, a scanner. Furthermore, in the exemplary embodiment, additional output channels may include, but not be limited to, an operator interface monitor.

The systems and methods described herein are not limited to the specific embodiments described herein, but rather, components of the systems and/or steps of the methods may be utilized independently and separately from other components and/or steps described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to provide details on the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A health monitor circuit for an electric machine, the health monitor circuit comprising:
at least one sensor configured to measure a parameter of the electric machine;
a communication interface; and
a microprocessor coupled to the at least one sensor, the communication interface, and a memory, the microprocessor configured to:
periodically collect time samples of the parameter measured by the at least one sensor;
transmit factors of the time samples to the memory;
perform a high resolution fast-Fourier transform (FFT) on the factors;
extrapolate results of the high resolution FFT to a produce a high resolution frequency domain waveform;
filter the high resolution frequency domain waveform by a parameter; and
transmit, via the communication interface, the filtered frequency domain waveform to a remote system for further processing.

2. The health monitor circuit of claim 1, wherein the microprocessor is further configured to generate a time domain data set based on the factors of the time samples.

3. The health monitor circuit of claim 2, wherein the microprocessor is further configured to generate a compressed data set comprising data based on the high resolution frequency domain waveform.

4. The health monitor circuit of claim 3, wherein the microprocessor is further configured to generate the compressed data set such that the compressed data set is orders of magnitude smaller than the time domain data set.

5. The health monitor circuit of claim 1, wherein the microprocessor is configured to filter the high resolution frequency domain waveform by a parameter to remove peaks below a configurable threshold.

6. The health monitor circuit of claim 1, wherein the at least one sensor comprises at least one of an ambient temperature sensor, an ambient humidity sensor, a barometric pressure sensor, an acceleration sensor, and a current sensor.

7. The health monitor circuit of claim 1, wherein the communication interface is further in communication with a motor controller coupled to the electric machine.

8. A method for monitoring the health of an electric machine, wherein the electric machine comprises at least one sensor configured to measure a parameter of the electric machine, a communication interface, and a microprocessor coupled to the at least one sensor, the communication interface, and a memory, the method comprising:
periodically collecting time samples of the parameter measured by at least one sensor;
transmitting factors of the time samples to the memory;
performing a high resolution fast-Fourier transform (FFT) on the factors;
extrapolating results of the high resolution FFT to a produce a high resolution frequency domain waveform;
filtering the high resolution frequency domain waveform by a parameter; and
transmitting, via the communication interface, the filtered frequency domain waveform to a remote system for further processing.

9. The method of claim 8, further comprising generating a time domain data set based on the factors of the time samples.

10. The method of claim 9, further comprising generating a compressed data set comprising data based on the high resolution frequency domain waveform.

11. The method of claim 10, further comprising generating the compressed data set such that the compressed data set is orders of magnitude smaller than the time domain data set.

12. The method of claim 8, further comprising filtering the high resolution frequency domain waveform by a parameter to remove peaks below a configurable threshold.

13. The method of claim 8, wherein the at least one sensor comprises at least one of an ambient temperature sensor, an ambient humidity sensor, a barometric pressure sensor, an acceleration sensor, and a current sensor.

14. A health monitor system, comprising:
an electric machine; and
a health monitor circuit coupled to the electric machine, the health monitor circuit comprising:
at least one sensor configured to measure a parameter of the electric machine;
a communication interface; and
a microprocessor coupled to the at least one sensor, the communication interface, and a memory, the microprocessor configured to:
periodically collect time samples of the parameter measured by the at least one sensor;
transmit factors of the time samples to the memory;
perform a high resolution fast-Fourier transform (FFT) on the factors;
extrapolate results of the high resolution FFT to a produce a high resolution frequency domain waveform;
filter the high resolution frequency domain waveform by a parameter; and
transmit, via the communication interface, the filtered frequency domain waveform to a remote system for further processing.

15. The health monitor system of claim 14, wherein the microprocessor is further configured to generate a time domain data set based on the factors of the time samples.

16. The health monitor system of claim 15, wherein the microprocessor is further configured to generate a compressed data set comprising data based on the high resolution frequency domain waveform.

17. The health monitor system of claim 16, wherein the microprocessor is further configured to generate the compressed data set such that the compressed data set is orders of magnitude smaller than the time domain data set.

18. The health monitor system of claim 14, wherein the microprocessor is configured to filter the high resolution frequency domain waveform by a parameter to remove peaks below a configurable threshold.

19. The health monitor system of claim 14, wherein the at least one sensor comprises at least one of an ambient temperature sensor, an ambient humidity sensor, a barometric pressure sensor, an acceleration sensor, and a current sensor.

20. The health monitor system of claim 14, wherein the communication interface is further in communication with a motor controller coupled to the electric machine.
